(19) United States
(12) Patent Application Publication
(10) Pub. No.: US 2024/0396399 A1
(43) Pub. Date: Nov. 28, 2024

(54) ELECTROMAGNETIC ROTARY DRIVE AND A CENTRIFUGAL PUMP

(71) Applicant: Levitronix GmbH, Zürich (CH)

(72) Inventors: Marcel STETTLER, Zofingen (CH); Daniel STEINERT, Bülach (CH); Natale BARLETTA, Zürich (CH)

(21) Appl. No.: 18/651,566

(22) Filed: Apr. 30, 2024

(30) Foreign Application Priority Data
May 22, 2023 (EP) 23174493.9

(51) Int. Cl. H02K 5/08; H02K 3/32; H02K 9/22

(52) U.S. Cl. CPC H02K 5/08; H02K 3/32; H02K 9/227; H02K 2203/03

(57) ABSTRACT

An electromagnetic rotary drive includes a motor and a control. The motor includes a stator, with which a rotor can be magnetically driven without contact and magnetically levitated without contact with respect to the stator. The rotor is magnetically levitated in a radial plane perpendicular to the axial direction, and the stator has a plurality of coil cores, each of which has a longitudinal leg which extends from a first end in the axial direction to a second end, and a transverse leg which is arranged at the second end of the longitudinal leg and in the radial plane A winding surrounds the longitudinal leg, and the control has electrical energy to control and supply the windings. A thermal separating element is arranged between the motor unit and the control unit, and reduces a direct heat flow from the motor unit into the control unit.

### CROSS-REFERENCE TO RELATED APPLICATION

This application claims priority to European Application No. 23174493.9, filed May 22, 2023, the contents of which are hereby incorporated by reference in its entirety.

### BACKGROUND

### Technical Field

The disclosure relates to an electromagnetic rotary drive and to a centrifugal pump having such an electromagnetic rotary drive.

### Background Information

Electromagnetic rotary drives are known which are designed and operated according to the principle of the bearingless motor. The term bearingless motor means an electromagnetic rotary drive in which a rotor is supported completely magnetically with respect to the stator, wherein no separate magnetic bearings are provided. For this purpose, the stator is designed as a bearing and drive stator, which is both the stator of the electric drive and the stator of the magnetic bearing. A magnetic rotating field can be generated with the electrical windings of the stator, which on the one hand exerts a torque on the rotor, which effects its rotation about a desired axis of rotation and which, on the other hand, exerts an arbitrarily adjustable transverse force on the rotor so that its radial position can be actively controlled or regulated. Thus, three degrees of freedom of the rotor can be actively regulated, namely its rotation and its radial position (two degrees of freedom). With respect to three further degrees of freedom, namely its position in the axial direction and tilting with respect to the radial plane perpendicular to the desired axis of rotation (two degrees of freedom), the rotor is passively magnetically supported or stabilized by reluctance forces, i.e., it cannot be controlled. The absence of a separate magnetic bearing with a complete magnetic bearing of the rotor is the property, which gives the bearingless motor its name. In the bearing and drive stator, the bearing function cannot be separated from the drive function.

Such a bearingless motor has proven itself in a large number of applications. Due to the absence of mechanical bearings, the bearingless motor is in particular suitable for pumping, mixing or stirring devices, with which very sensitive substances are conveyed, for example blood pumps, or on which very high demands are made with respect to purity, for example in the pharmaceutical industry or in the biotechnological industry, or with which abrasive or aggressive substances are conveyed, which would very quickly destroy mechanical bearings, for example pumps or mixers for slurry, sulfuric acid, phosphoric acid or other chemicals in the semiconductor industry.

A further advantage of the principle of the bearingless motor is the design of the rotor as an integral rotor, which is both the rotor of the electromagnetic rotary drive and the rotor of the pump. In addition to the contactless magnetic bearing, the advantage here is a very compact and space-saving design.

In addition, the principle of the bearingless motor also allows designs, e.g., of centrifugal pumps, in which the rotor can be separated from the stator very easily. This is a very great advantage, because in this way, for example, the rotor or the pump unit comprising the rotor can be designed as a single-use part for single use. Today, such single-use applications often replace processes in which, due to the very high purity requirements, all those components that come into contact with the substances to be treated in the process previously had to be cleaned and sterilized in an elaborate manner, for example by means of steam sterilization. When designed for single use, those components that come into contact with the substances to be treated are only used exactly once and are then replaced with new, i.e., unused, single-use parts for the next application.

The pharmaceutical industry and the biotechnological industry can be named as examples here. Solutions and suspensions are frequently produced here that require careful and gentle conveying of substances.

An advantageous design that is known per se of an electromagnetic rotary drive, which can be designed according to the principle of the bearingless motor, is the design as a temple motor, which is disclosed for example in EP-A-3 232 549.

The characteristic feature of a temple motor is that the stator has a plurality of coil cores, each of which comprising a longitudinal leg, which substantially extends parallel to the axial direction. The axial direction refers to that direction which is defined by the desired axis of rotation of the rotor, i.e., the axis of rotation about which the rotor rotates in the operating state when it is in a centered and non-tilted position with respect to the stator in the radial plane, which is perpendicular to the axial direction. Each longitudinal leg extends from a first end in the axial direction to a second end. Each coil core comprises, in addition to the longitudinal leg, a transverse leg, which is provided in each case at the second end of the longitudinal leg, and which extends in the radial direction towards inside, i.e., substantially at a right angle to the longitudinal leg. The coil cores each have the shape of an L, wherein the transverse legs form the short legs of the L. The rotor is then arranged between the transverse legs.

The plurality of the longitudinal legs which extends in the axial direction, and which are reminiscent of the columns of a temple has given the temple motor its name.

In one design, the temple motor has, for example, six coil cores arranged circularly and equidistantly around the rotor (internal rotor). The first ends of the longitudinal legs are connected in the circumferential direction by a back iron, which serves to conduct the magnetic flux. The rotor comprises a magnetically effective core, for example a permanent magnetic disk or a permanent magnetic ring, which is arranged between the radially inwardly lying ends of the transverse legs and which rotates about the axial direction in the operating state, wherein the rotor is magnetically driven without contact and is magnetically supported without contact with respect to the stator.

There are also known such designs of the temple motor in which the magnetically effective core is designed in a permanent magnetic-free manner, i.e., without permanent magnets. Then, the magnetically effective core of the rotor is, for example, designed in a ferromagnetic manner and is made, for example, of iron, nickel-iron, cobalt-iron, silicon iron, mu-metal, or another ferromagnetic material.

Furthermore, designs are possible in which the magnetically effective core of the rotor comprises both ferromagnetic materials and permanent magnetic materials. For example, permanent magnets can be placed or inserted into a ferromagnetic base body. Such designs are advantageous, for example, if one wishes to reduce the costs of large rotors by saving permanent magnetic material.

The longitudinal legs carry windings to generate the electromagnetic rotating fields necessary for the magnetic drive and the magnetic bearing of the rotor. For example, the windings are designed such that one concentrated winding is wound around each longitudinal leg, i.e., the coil axis of each concentrated winding extends in each case in the axial direction. Here, it is typical for the temple motor that the coil axes of the concentrated windings are parallel to the desired axis of rotation and that the concentrated windings are not arranged in the radial plane in which the rotor or the magnetically effective core of the rotor is supported in the operating state.

### SUMMARY

In a design frequently used today for industrial applications, the motor unit, which comprises the bearing and drive stator for driving and bearing the rotor, is spatially separated from a control unit, which comprises the power electronics for controlling and supplying the windings of the stator, such as power converters or inverters for providing the current to be impressed into the windings or circuit breakers with which the windings are controlled. Then, the control unit is usually arranged spatially separated from the motor unit and connected to the motor unit via motor cables and sensor cables. It has been that thisresults in a large space requirement and a high complexity of the installation, for example due to the cabling between the motor unit and the control unit. This cabling also represents a cost factor. In addition, the transmission of sensor signals between the motor unit and the control unit, for example, can be susceptible to interference.

Attempts have also been made to arrange the control unit as close as possible to the motor unit. However, it has been determined that this results in significant thermal problems because large amounts of heat are produced by both the motor unit and the control unit, which are very difficult to dissipate without causing a strong thermal interaction between the motor unit and the control unit.

The heat generated in the motor unit during operation is based in particular on iron and copper losses. In the control unit, it is particularly the power electronics, for example the inverters or rectifiers, which generate heat during operation. If the motor unit and the control unit are therefore arranged spatially close to each other, there is a risk that the heat generated during operation cannot be dissipated sufficiently well, which can lead in particular to overheating of the electronic components, whereby their service life is significantly reduced.

It is therefore an object of the disclosure to propose an electromagnetic rotary drive, which is designed as a temple motor and which has a particularly compact design, wherein the control unit is protected against overheating. Furthermore, it is an object of the disclosure to propose a centrifugal pump having such a rotary drive.

The subject matter of the disclosure meeting these objects is characterized by the features disclosed herein.

According to the disclosure, an electromagnetic rotary drive is thus proposed, which is designed as a temple motor and comprises a motor unit and a control unit, wherein the motor unit is arranged in a motor housing which has a recess for receiving a ring-shaped or disk-shaped magnetically effective core of a rotor, wherein the motor unit comprises a stator, which is designed as a bearing and drive stator, with which the rotor can be magnetically driven without contact in the operating state about a desired axis of rotation, which defines an axial direction, and with which the rotor can be magnetically levitated without contact with respect to the stator, wherein the rotor is actively magnetically levitated in a radial plane perpendicular to the axial direction, wherein the stator has a plurality of coil cores, each of which comprising a longitudinal leg which extends from a first end in the axial direction to a second end, and a transverse leg which is arranged at the second end of the longitudinal leg and in the radial plane, and which extends from the longitudinal leg in a radial direction, wherein the coil cores are arranged around the recess with respect to a circumferential direction, and wherein at least one concentrated winding is provided at each longitudinal leg, which winding surrounds the respective longitudinal leg, and wherein the control unit is equipped with electrical energy to control and supply the windings. With respect to the axial direction, a thermal separating element is arranged between the motor unit and the control unit, which separating element rests against the motor unit and the control unit, and which reduces a direct heat flow from the motor unit into the control unit.

The thermal separating element serves to thermally decouple the motor unit and the control unit from each other. In this way, the heat input from the motor unit into the control unit is significantly reduced so that the electronic components in the control unit, such as the power electronics, are very well protected against the heat generated in the motor unit. In this way, overheating of the control unit can be reliably avoided.

The thermal separating element is a large heat reservoir that absorbs heat from both the motor unit and the control unit and releases it into the environment, for example via the surface of the motor housing, so that only a very small amount of heat-if any-flows from the motor unit into the control unit or vice versa, from the control unit into the motor unit.

Due to the thermal separating element, a particularly compact design of the electromagnetic rotary drive is enabled, because the control unit can be arranged very close to the motor unit. The motor unit and the control unit are only separated from each other by the thermal separating element, which at least significantly reduces a direct heat flow from the motor unit into the control unit—or vice versa from the control unit into the motor unit.

Due to this compact design, in which the control unit is arranged adjacent to the motor unit, the space requirement, and the complexity of the installation reduces, since there is no need to provide separate and spatially more distant locations for the motor unit on the one hand and the control unit on the other. This also reduces the effort for the connection, for example the cabling between the motor unit and the control unit.

In addition, the signal path between the motor unit and the control unit, for example for sensor signals, can be considerably shortened, which significantly reduces the susceptibility of the signal path to interference.

Furthermore, the overall cost of manufacturing and installing a device that has an electromagnetic rotary drive according to the disclosure are also reduced by the compact design.

In particular in the case of powerful rotary drives which have an output of 2 kilowatts (kW) or more, for example, it is preferred that a cooling conduit is arranged in the thermal separating element through which a cooling fluid can flow. The amount of heat dissipated per time from the thermal separating element can be increased by this measure.

In a preferred embodiment, with respect to the axial direction, a circuit board with electronic components is arranged between the windings and the transverse legs. The circuit board is designed, for example, as an electronic print or PCB (Printed Circuit Board), which can contain, for example, electronic components for the control or operation of sensors, for example position sensors or magnetic field sensors, or components for the evaluation of the signals supplied by sensors.

Such embodiments are possible in which the control unit comprises a separate control housing which is arranged adjacent to the motor housing with respect to the axial direction, wherein the thermal separating element is arranged between the motor housing and the control housing with respect to the axial direction. In this case, the control housing is a separate housing, distinct from the motor housing, in which the electronic components of the control unit are arranged.

Preferably, the motor housing and the control housing are arranged without direct physical contact with each other. With respect to the axial direction, the thermal separating element is arranged between the motor unit and the control unit in such a way that the motor housing and the control housing have no direct physical contact with each other. On the one side, the motor housing rests against the thermal separating element and on the other side the control housing, wherein the motor housing and the control housing do not touch each other but are separated from each other by the separating element arranged between them.

According to a preferred embodiment, the stator comprises a thermal conductive element with a thermal conductive plate which is arranged between the coil cores and the thermal separating element with respect to the axial direction, and which is in physical contact with the coil cores or with a back iron by which the first ends of all longitudinal legs are connected for conducting the magnetic flux. The thermal conductive plate ensures very good thermal contact between the coil cores or the back iron and the thermal separating element, so that the heat generated during operation is dissipated very efficiently from the coil cores or the back iron. The heat generated in the stator during operation is in particular the heat generated by the concentrated windings, i.e., for example the copper losses, as well as the heat generated by iron losses in the coil cores or the back iron.

It is a further advantageous measure that the thermal conductive element comprises a plurality of conductive teeth connected to the thermal conductive plate, wherein each conductive tooth extends in the axial direction in each case and is arranged radially inwardly with respect to the windings in the interior space surrounded by the windings. Here, the conductive teeth are arranged as close as possible to the windings with respect to the radial direction, so that the conductive teeth can absorb and dissipate the heat generated by the windings and the heat generated in the coil cores as well as possible. The thermal conductive element, i.e. in particular the thermal conductive plate and the conductive teeth, are made of a material with good thermal conductivity, for example a metallic material. A preferred material for the thermal conductive element is aluminum.

Furthermore, it is preferred that each conductive tooth is arranged immediately adjacent to one of the longitudinal legs or one of the windings with respect to the radial direction.

For example, the number of conductive teeth is equal to the number of coil cores. Preferably, with respect to the radial direction, exactly one conductive tooth is arranged adjacent to each coil core and the winding arranged thereon.

It is a further preferred measure that a recess is provided in each case between two adjacent conductive teeth as viewed in the circumferential direction, which recess extends into the region of the first ends of the longitudinal legs with respect to the axial direction. Due to these recesses between the conductive teeth, eddy current losses, which result from the stray fields of the current in the windings, are reduced as far as possible.

According to a further preferred embodiment, the control unit is arranged in the motor housing. In this embodiment, no separate control housing is thus provided but the control unit is also arranged in the motor housing.

It is a preferred measure in this embodiment that the thermal separating element is an integral part of the motor housing. For this purpose, the thermal separating element is preferably designed in one piece with the motor housing. Due to this measure, the thermal resistance can be significantly reduced.

Furthermore, it is preferred that the motor housing comprises an inner cup which is substantially designed in a cylindrical manner, and which is arranged radially inwardly with respect to the windings in the interior space surrounded by the windings. This inner cup can very efficiently absorb the heat generated by the windings, e.g. heat caused by copper losses, as well as the heat generated in the coil cores and the back iron, e.g. heat generated by iron losses, and then release it to the environment via the outside of the motor housing.

Preferably, the inner cup extends over the entire length of the windings with respect to the axial direction.

Furthermore, a centrifugal pump for conveying a fluid is proposed by the disclosure, which comprises an electromagnetic rotary drive, which is designed according to the disclosure, as well as a rotor with a magnetically effective core, which is arranged in the recess in the motor housing, wherein the rotor is designed as the rotor of the centrifugal pump, wherein the rotor of the electromagnetic rotary drive is designed as the rotor of the centrifugal pump.

Preferably, the centrifugal pump comprises a pump housing comprising a pump inlet and a pump outlet for the fluid to be conveyed, wherein the rotor is arranged in the pump housing and comprises a plurality of vanes for conveying the fluid. The pump housing is designed in such a way that it can be inserted into the recess in the motor housing such that the magnetically effective core of the rotor is surrounded by the transverse legs.

Further advantageous measures and embodiments of the disclosure are apparent from the dependent claims.

### BRIEF DESCRIPTION OF THE DRAWINGS

In the following, embodiments of the disclosure will be explained in more detail with reference to the drawings.

FIG. 1 illustrates a perspective exploded view of a first embodiment of an electromagnetic rotary drive according to the disclosure,

FIG. 2 illustrates a perspective view of the stator of the first embodiment, partly in section, as well as the magnetically effective core of a rotor,

FIG. 3 illustrates a perspective view of the thermal conductive element of the first embodiment,

FIG. 4 illustrates a schematic sectional view of the first variant of the first embodiment in a section in the axial direction,

FIG. 5 illustrates a sectional view of the thermal separating element of the first variant in a section perpendicular to the axial direction,

FIG. 6 illustrates a schematic sectional view of the second variant of the first embodiment in a section in the axial direction,

FIG. 7 illustrates a perspective exploded view of a second embodiment of an electromagnetic rotary drive according to the disclosure,

FIG. 8 illustrates a schematic sectional view of the second embodiment in a section in the axial direction,

FIG. 9 illustrates a sectional view of the thermal separating element of the second embodiment in a section perpendicular to the axial direction,

FIG. 10 illustrates a schematic sectional view of a variant of the second embodiment in a section in the axial direction,

FIG. 11 illustrates a perspective view of an embodiment of a centrifugal pump according to the disclosure, wherein the pump unit is represented separately from the stator, and

FIG. 12 illustrates a schematic sectional view of the embodiment from FIG. 11 in a section in the axial direction.

### DETAILED DESCRIPTION

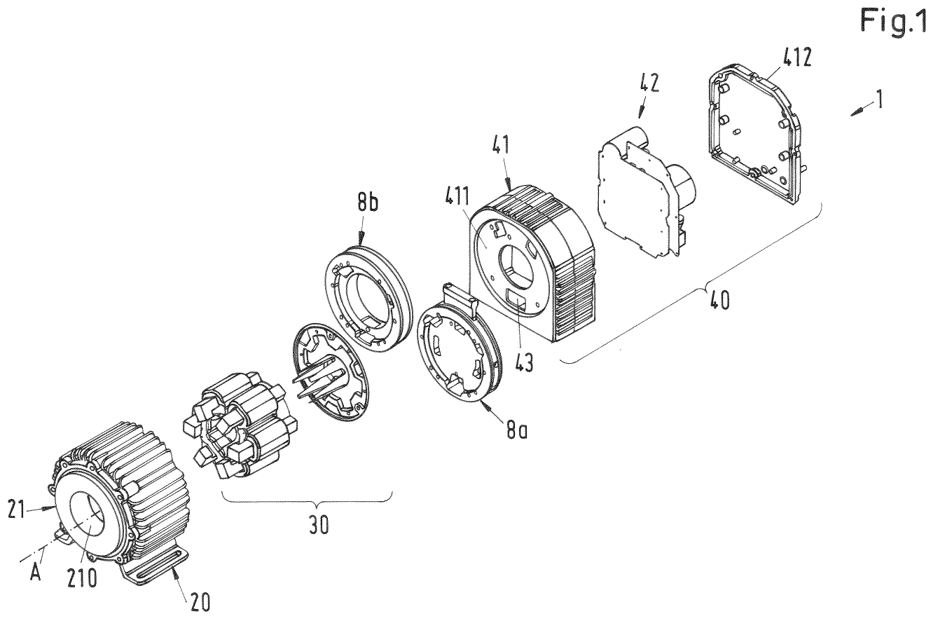

FIG. 1 shows a perspective exploded view of a first embodiment of an electromagnetic rotary drive according to the disclosure, which is designated in its entirety by the reference sign 1. The electromagnetic rotary drive 1 comprises a motor unit 30, which is arranged in a motor housing 20, and a control unit (electronic controller) 40 for controlling and supplying the motor unit (motor) 30 with electrical energy. In the first embodiment, the control unit 40 comprises a separate control housing 41, i.e. different from the motor housing 20, in which the various electronic or electrical components 42 of the control unit 40 are arranged. A thermal separating element 8a or 8b is provided between the control housing 41 and the motor housing 20, which rests against the motor unit 30 and the motor housing 20 on the one hand, and the control unit 40 on the other hand. The thermal separating element 8a, 8b reduces or prevents a direct heat flow from the motor unit 30 into the control unit 40 or also vice versa from the control unit 40 into the motor unit 30. The thermal separating element 8a, 8b is designed such that the motor housing 20 and the control housing 41 have no direct physical contact with each other but are separated from each other by the thermal separating element 8a, 8b.

The motor housing 20 and the control housing 41 are preferably made of a metallic material. A particularly suitable material for the motor housing 20 and the control housing 41 is aluminum, wherein in particular the externally exposed sides of the motor housing 20 and the control housing 41 can be designed with a coating, for example to improve the chemical resistance.

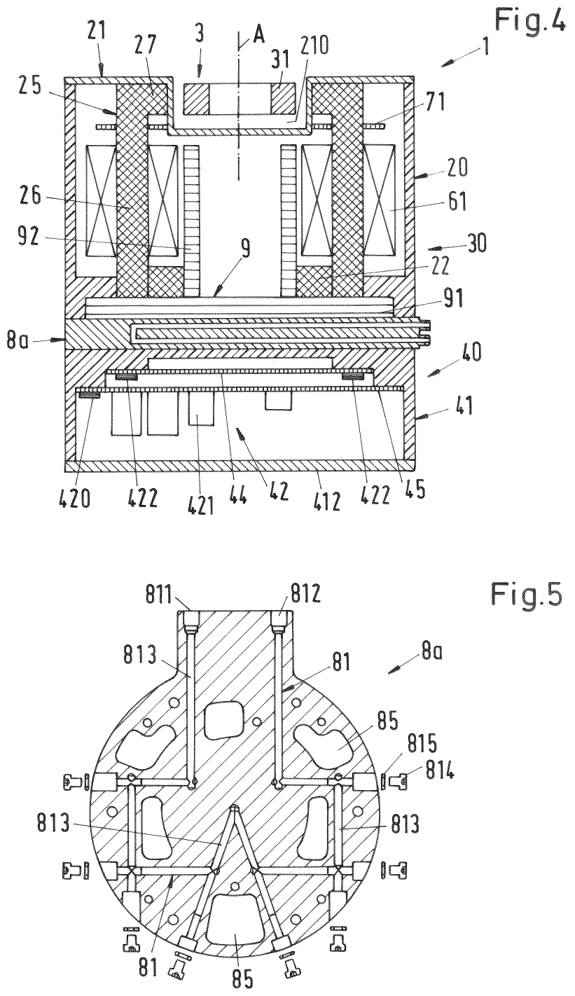

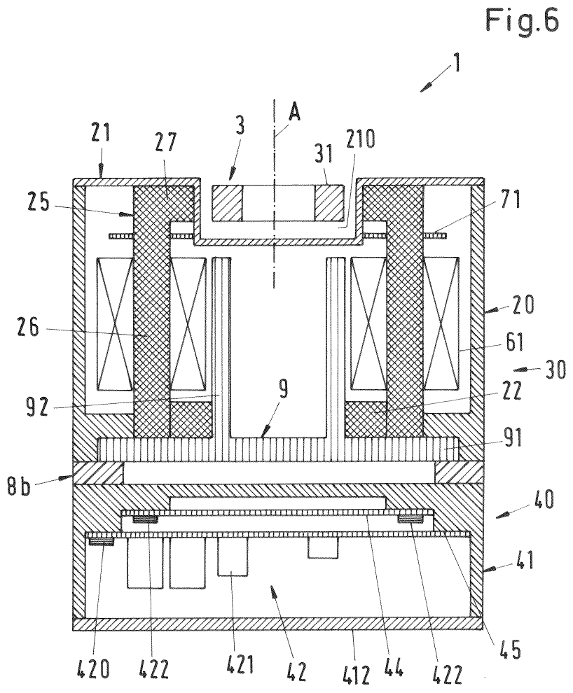

There are two possibilities for the design of the thermal separating element 8a, 8b, as will be explained in more detail below. According to a first variant of the first embodiment, the thermal separating element 8a is designed as an active cooling element through which a cooling fluid can flow. In a schematic sectional view, FIG. 4 shows this first variant of the first embodiment with the thermal separating element 8a. According to a second variant of the first embodiment, the thermal separating element 8b is designed as a passive thermal separating element 8b, through which a cooling fluid does not flow. In this embodiment as a passive separating element 8b, the separating element 8b thermally isolates the motor unit 30 from the control unit 40, so that there is at most a low heat flow from the control unit 40 to the motor unit 30 or vice versa from the motor unit 30 to the control unit 40. The heat generated during operation is primarily dissipated to the environment via convection, for example via the surface of the motor housing 20. In a schematic sectional view, FIG. 6 shows this second variant of the first embodiment with the thermal separating element 8b.

The representation in FIG. 1 is to be understood in such a way that the thermal separating element 8a, 8b is designed either as an active thermal separating element 8a (see FIG. 4) or as a passive thermal separating element 8b (FIG. 6). Thus, FIG. 1 illustrates the first and the second variant of the first embodiment.

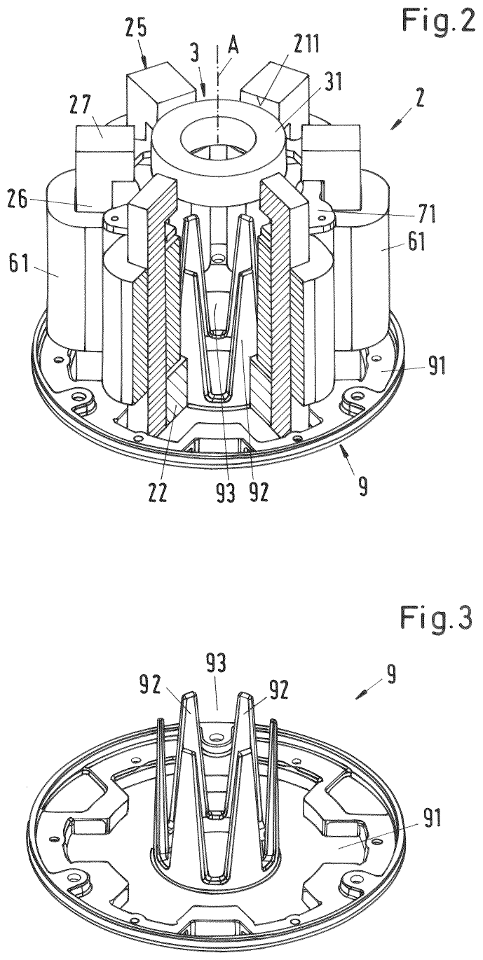

The motor housing 20 has a recess 210 in one of its end faces, which is designed to receive a magnetically effective core 31 (FIG. 2) of a rotor 3.

Preferably, the recess 210 is provided in a separate rotor cup 21 (see also FIG. 4), wherein the rotor cup 21 is designed as a cover of the motor housing 20, which closes the motor housing 20 at one of its axial ends as an axial end face. The rotor cup 21 is firmly connected to the motor housing 20, for example screwed or glued, or connected to the motor housing 20 by a press fit—with or without an O-ring. The rotor cup 21 closes off the motor housing 20, preferably in a hermetically sealed manner. The separate rotor cup 21 is preferably made of a plastic, for example polypropylene.

The electromagnetic rotary drive 1 is designed as a temple motor. The motor unit 30 comprises a stator 2. For better understanding, FIG. 2 also shows a perspective view of the stator 2, wherein the motor housing 20 is not represented in FIG. 2 and a segment is cut out of the stator 2.

The stator 2 has a plurality of coil cores 25—here six coil cores 25—each of which, according to the embodiment as a temple motor, comprises a longitudinal leg 26 which extends in an axial direction A, and a transverse leg 27 arranged perpendicular to the longitudinal leg 26, which extends in a radial direction and is delimited by an end face 211. The coil cores 25 are arranged equidistantly on a circular line, so that the end faces 211 surround the recess 210, into which the rotor 3 with the magnetically effective core 31 can be inserted. Exactly one concentrated winding 61 is provided at each longitudinal leg 26, which surrounds the respective longitudinal leg 26.

In other embodiments, more than one concentrated winding 61, for example two concentrated windings in each case, can be provided at each longitudinal leg 26, each of which surrounds the respective longitudinal leg 26 and which are arranged adjacent to each other with respect to the axial direction A.

The longitudinal legs 26 are each designed in a rod-shaped manner or substantially in a rod-shaped manner. In particular, the longitudinal legs 26 can also be designed as represented, for example, in FIG. 3 or in FIG. 5 of EP 4 084 304 A1.

The rotor 3 can be magnetically levitated without contact with respect to the stator 2. Furthermore, the rotor 3 can be magnetically driven without contact by means of the stator 2 for rotation about a desired axis of rotation. Here, the desired axis of rotation refers to that axis about which the rotor 3 rotates in the operating state when the rotor 3 is in a centered and not tilted position with respect to the stator 2, as represented in FIG. 2 for the magnetically effective core 31 of the rotor 3. This desired axis of rotation defines the axial direction A. Usually, the desired axis of rotation defining the axial direction A corresponds to the central axis of the stator 2.

In the following, a radial direction refers to a direction, which stands perpendicular on the axial direction A.

It is understood that the number of six coil cores 25 is to be understood only as an example. Of course, such embodiments are also possible in which the stator 2 has fewer than six, e.g., five, coil cores 25, or such embodiments in which the stator 2 has more than six, e.g., seven or eight, coil cores 25.

The rotor 3 comprises the magnetically effective core 31, which is designed in a ring-shaped or disk-shaped manner. According to the representation in FIG. 2, the magnetically effective core 31 is designed as a ring and defines a magnetic center plane. Alternatively, the magnetically effective core 31 can also be designed as a disk. As a rule, in a disk-shaped or ring-shaped magnetically effective core 31, the magnetic center plane is the geometric center plane of the magnetically effective core 31 of the rotor 3, which is perpendicular to the axial direction A. In the operating state, the magnetically effective core 31 is levitated in a radial plane which stands perpendicular on the axial direction A.

The radial plane is that plane in which the magnetically effective core 31 of the rotor 3 is actively magnetically levitated between the end faces 211 in the stator 2 in the operating state. If the rotor 3 is not tilted and is not deflected in the axial direction A, the magnetic center plane lies in the radial plane. The radial plane defines the x-y plane of a Cartesian coordinate system whose z-axis runs in the axial direction A.

The radial position of the magnetically effective core 31 or the rotor 3 denotes the position of the rotor 3 in the radial plane.

Since it is sufficient for the understanding of the disclosure, only the magnetically effective core 31 of the rotor 3 is shown in each case in FIGS. 2, 4, 6, 8 and 10 in the drawing. It is understood that the rotor 3 can, of course, comprise further components such as jackets or encapsulations, which are preferably made of a plastic, or of a metal, or of a metal alloy, or of a ceramic or a ceramic material. Furthermore, the rotor 3 can also comprise vanes for mixing, agitating or pumping fluids or other components.

The stator 2 is arranged in the motor housing 20 (see FIG. 1), which completely encloses the stator 2, so that the entire stator 2 is arranged inside the motor housing 20. For better understanding, the motor housing 20 is not represented in FIG. 2, so that the components of the stator 2 arranged in the motor housing 20 can be recognized.

Particularly preferably, the motor housing 20 is designed as a hermetically sealed motor housing 20, which completely encapsulates the stator 2. The motor housing 20 is preferably filled with a thermally conductive casting compound, for example with an epoxy resin or with a polyurethane, so that the stator 2 and possibly further components which are arranged inside the motor housing 20 are surrounded by the casting compound. As a result, the general thermal resistance is reduced, and vibrations are attenuated.

When the rotor 3 is inserted into the recess 210 in the motor housing 20, the rotor 3 and in particular the magnetically effective core 31 of the rotor 3 are surrounded by the radially outwardly arranged transverse legs 27 of the coil cores 25 of the stator 2. Thus, the transverse legs 27 form a plurality of pronounced stator poles-here six stator poles. The longitudinal legs 26 of the coil cores 25 each extend in the axial direction A from a first end, which is the lower end according to the representation (FIG. 2), to a second end, which is the upper end according to the representation. The transverse legs 27 are arranged at the upper ends of the longitudinal legs 26 and in the radial plane. Each transverse leg 27 extends in the radial direction towards the rotor 3.

When the magnetically effective core 31 of the rotor 3 is in its desired position during operation, the magnetically effective core 31 is centered between the end faces 211 of the transverse legs 27 so that the transverse legs 27 arranged in the radial plane are also located in the magnetic center plane. According to the representation, the concentrated windings 61 are arranged below the radial plane and are aligned such that their coil axes each extend in the axial direction A.

All first ends of the longitudinal legs 26—i.e., the lower ends according to the representation—are connected to one another by a back iron 22. The back iron 22 is preferably designed in a ring-shaped manner. Such embodiments are possible in which the back iron 22 extends radially inwardly along all first ends of the longitudinal legs 26. However, it is also possible that the back iron 22 has a plurality of recesses along its circumference, each of which receives one of the first ends. In other embodiments, the back iron 22 can also comprise a plurality of ring segments, each of which is arranged in each case between two circumferentially adjacent coil cores 25 in the region of the first ends.

In order to generate the electromagnetic rotating fields required for the magnetic drive and the magnetic levitation of the rotor 3, the longitudinal legs 26 of the coil cores 25 carry the windings 61 designed as concentrated windings 61, wherein in the first embodiment exactly one concentrated winding 61 is arranged around each longitudinal leg 26. In the operating state, those electromagnetic rotating fields are generated with these concentrated windings 61 with which a torque is effected on the rotor 3 and with which an arbitrarily adjustable transverse force can be exerted on the rotor 3 in the radial direction, so that the radial position of the rotor 3, i.e. its position in the radial plane perpendicular to the axial direction A, can be actively controlled or regulated.

The “magnetically effective core 31” of the rotor 3 refers to that region of the rotor 3 which magnetically interacts with the stator 2 for torque generation and the generation of magnetic levitation forces.

As already mentioned, the magnetically effective core 31 is designed in a ring-shaped manner in this embodiment. Furthermore, the magnetically effective core 31 is designed in a permanent magnetic manner. For this purpose, the magnetically effective core 31 can comprise at least one permanent magnet, but also several permanent magnets, or—as in the first embodiment described here-consist entirely of a permanent magnetic material, so that the magnetically effective core 31 is the permanent magnet. For example, the magnetically effective core 31 is magnetized in the radial direction.

Those ferromagnetic or ferrimagnetic materials, which are magnetically hard, that is which have a high coercive field strength, are typically called permanent magnets. The coercive field strength is that magnetic field strength which is required to demagnetize a material. Within the framework of this application, a permanent magnet is understood as a matter or a material, which has a coercive field strength, more precisely a coercive field strength of the magnetic polarization, which amounts to more than 10′000 A/m.

Such embodiments are also possible in which the magnetically effective core 31 is designed in a permanent magnet-free manner, i.e., without permanent magnets. The rotor 3 is then designed, for example, as a reluctance rotor. Then, the magnetically effective core 31 of the rotor 3 is made of a soft magnetic material, for example. Suitable soft magnetic materials for the magnetically effective core 31 are, for example, ferromagnetic or ferrimagnetic materials, i.e., in particular iron, nickel-iron, cobalt-iron, silicon iron, mu-metal.

Furthermore, embodiments are possible in which the magnetically effective core 31 of the rotor 3 comprises both ferromagnetic materials and permanent magnetic materials. For example, permanent magnets can be placed or inserted in a ferromagnetic base body. Such embodiments are advantageous, for example, if one wishes to reduce the costs of large rotors by saving permanent magnetic material.

Embodiments are also possible in which the rotor 3 is designed according to the principle of a cage rotor.

Both the ring-shaped back iron 22 and the coil cores 25 of the stator 2 are each made of a soft magnetic material because they serve as flux conductive elements for conducting the magnetic flux.

Suitable soft magnetic materials for the coil cores 25 and the back iron 22 are, for example, ferromagnetic or ferrimagnetic materials, i.e., in particular iron, nickel-iron, cobalt-iron, silicon iron or mu-metal. In this case, a design as a stator sheet stack is preferred for the stator 2, in which the coil cores 25 and the back iron 22 are designed in sheet metal, i.e., they consist of several thin sheet metal elements, which are stacked.

Furthermore, it is possible that the coil cores 25 and the back iron 22 are made of pressed and subsequently sintered grains of the aforementioned materials. The metallic grains are preferably embedded in a plastic matrix so that they are at least partially electrically insulated from one another, whereby eddy current losses can be minimized. Thus, soft magnetic composites which include electrically insulated and compressed metal particles are also suitable for the stator. In particular, these soft magnetic composites, which are also designated as SMC (Soft Magnetic Composites), can includes iron powder particles coated with an electrically insulating layer. These SMC are then formed into the desired shape by powder metallurgy processes.

During operation of the electromagnetic rotary drive 1, the magnetically effective core 31 of the rotor 3 interacts with the stator 2 according to the principle of the bearingless motor described above, in which the rotor 3 can be magnetically driven without contact and can be magnetically levitated without contact with respect to the stator 2. For this purpose, the stator 2 is designed as a bearing and drive stator, with which the rotor 3 can be magnetically driven without contact in the operating state about the desired axis of rotation—i.e., it can be set into rotation—and can be magnetically levitated without contact with respect to the stator 2. In this case, three degrees of freedom of the rotor 3 can be actively regulated, namely its position in the radial plane and its rotation. With respect to its axial deflection from the radial plane in the axial direction A, the magnetically effective core 31 of the rotor 3 is passively magnetically stabilized by reluctance forces, i.e., it cannot be controlled. Also, with respect to the remaining two degrees of freedom, namely tilts with respect to the radial plane perpendicular to the desired axis of rotation, the magnetically effective core 31 of the rotor 3 is also passively magnetically stabilized. Due to the interaction of the magnetically effective core 31 with the coil cores 25, the rotor 3 is thus passively magnetically levitated or passively magnetically stabilized in the axial direction A and against tilts (a total of three degrees of freedom) and actively magnetically levitated in the radial plane (two degrees of freedom).

In the framework of this application as is generally the case, an active magnetic levitation is also referred to one which can be actively controlled or regulated, for example by means of the electromagnetic rotating fields generated by the concentrated windings 61. A passive magnetic levitation or a passive magnetic stabilization is one that cannot be controlled or regulated. The passive magnetic levitation or stabilization is based, for example, on reluctance forces, which bring the rotor 3 back again to its desired position when it is deflected from its desired position, e.g., in the case of a displacement or deflection in the axial direction A or in the case of tilting.

A radial levitation or a levitation in a radial manner refers to a levitation of the rotor 3 with which the radial position of the rotor 3 can be stabilized, i.e., a levitation which levitates the rotor 3 in the radial plane and thus with respect to its radial position.

An axial levitation or a levitation in an axial manner and an axial stabilization or a stabilization in an axial manner, respectively, refers to a levitation or a stabilization of the rotor 3 with which, on the one hand, the position of the rotor 3 is stabilized with respect to the axial direction A and with which, on the other hand, the rotor 3 is stabilized against tilts. Such tilts represent two degrees of freedom and designate deflections in which the momentary axis of rotation of the rotor 3 no longer points exactly in the axial direction A but encloses an angle different from zero with the desired axis of rotation. In the case of a tilt, the magnetic center plane thus no longer lies in or parallel to the radial plane, but the magnetic center plane encloses an angle different from zero with the radial plane.

In a bearingless motor, in contrast to classical magnetic bearings, the magnetic levitation and the drive of the motor are realized by means of electromagnetic rotating fields. Typically, in the bearingless motor, the magnetic drive and levitation function is generated by the superposition of two magnetic rotating fields, which are usually designated as drive and control fields. These two rotating fields generated with the windings of the stator usually have a pole pair number that differs by one. For example, if the drive field has the pole pair number p, the control field has the pole pair number p+1 or p−1. In this case, tangential forces acting on the magnetically effective core 31 in the radial plane are generated by the drive field, causing a torque, which causes the rotation about the axial direction A. Due to the superposition of the drive field and the control field, it is also possible to generate an arbitrarily adjustable transverse force on the magnetically effective core 31 in the radial plane, with which the position of the magnetically effective core 31 in the radial plane can be regulated. Thus, it is not possible to divide the electromagnetic flux generated by the concentrated windings 61 into an (electro-) magnetic flux that only provides for driving the rotation and an (electro-) magnetic flux that only realizes the magnetic levitation.

To generate the drive and the control field, it is possible on the one hand to use two different winding systems, namely one to generate the drive field and one to generate the control field. The coils for generating the drive field are then usually referred to as drive coils and the coils for generating the control field as control coils.

Thus, for example, two concentrated windings can be provided on each coil core 25 in each case, which are arranged adjacent to each other with respect to the axial direction A. One of the windings is used as the drive coil, while the other concentrated winding adjacent to it is used as the control coil. The current impressed in these coils is then referred to as the drive current and the control current, respectively. The drive field, which is an electromagnetic rotating field, is then generated with the totality of all the drive coils, while the control field, which is also an electromagnetic rotating field and which is superimposed on the drive field, is generated with the totality of the control coils. Due to the superposition of the drive field and the control field, the tangential forces on the rotor 3 can then be generated, which generate the torque for driving the rotation, as well as an arbitrarily adjustable transverse force in the radial plane, with which the position of the magnetically effective core 31 in the radial plane can be actively regulated.

However, such embodiments are also possible in which the drive and levitation function is generated with only one single winding system, so that there is no distinction between drive and control coils. Such a design is provided in the first embodiment. As FIG. 2 shows, exactly one concentrated winding 61 is provided on each coil core 25 in each case, wherein both the drive field and the control field are generated with the totality of the concentrated windings 61. This can be realized in such a way that the values for the drive and the control current determined in each case by the control unit 40 are mathematically added or superimposed—that is e.g., with the aid of software—and the resulting total current is impressed into the respective concentrated winding 61. Of course, in this case it is no longer possible to distinguish between control and drive coils. Then, there is only one winding system in whose concentrated windings 61 the mathematically determined sum of the drive and the control current is impressed.

In the first embodiment, a first circuit board 71 (FIG. 2) with electronic components not represented in more detail is also provided. The circuit board 71 is preferably designed as an electronic print or PCB (printed circuit board). For example, such components can be provided on the circuit board 71 that are used for the control of sensors (not represented) and/or for the evaluation of the measurement signals determined by sensors. Such sensors comprise, for example, position sensors for determining the current position of the rotor 3. The circuit board 71 and the electronic components provided on it, respectively, are signal-connected to the control unit 40.

The circuit board 71 is substantially designed in a ring-shaped manner and arranged parallel to the radial plane. Preferably, the ring-shaped circuit board 71 is arranged radially inwardly with respect to the coil cores 25, wherein the circuit board 71—as can be seen in FIG. 2—can also extend into the interspaces between the longitudinal legs 26 of adjacent coil cores 25.

With respect to the axial direction A, the circuit board 71 is arranged between the windings 61b and the transverse legs 27 of the coil cores 25. According to the representation in FIG. 2, the circuit board 71 is thus arranged below and adjacent to the transverse legs 27, which are arranged around the magnetically effective core 31 of the rotor 3.

The control unit 40 comprises the electrical or electronic components 42, which are necessary for controlling and supplying the windings 61 with electrical energy. In particular, these are rectifiers or inverters with which the voltage or current for supplying the windings 61 is provided, circuit breakers 420 (FIG. 4) for the rectifiers, filter components 421, e.g. capacitors or inductors for smoothing the direct current, circuit breakers 422 for controlling the windings 61, with which the current supplied to the windings 61 is switched, regulation and control components for controlling the contactless magnetic levitation and the contactless magnetic drive, evaluation components for sensor signals. The rectifier for providing the supply voltage for the windings 61 is preferably designed with a power factor correction filter (PFC: Power Factor Correction or Power Factor Compensation) in order to reduce the distortion reactive power and thus to increase the power factor of the rectifier.

In the first embodiment of the rotary drive according to the disclosure, the stator 2 further comprises a thermal conductive element 9 for dissipating the heat which is generated during operation in the windings 61, the coil cores 25 and the back iron 22. This heat is based in particular on the copper losses in the windings 61 as well as the iron losses in the coil cores 25 and the back iron 22. The thermal conductive element 9 serves to dissipate the heat generated in the windings 61, the coil cores 25 and the back iron 22 as well as possible. For better understanding, FIG. 3 still shows a perspective view of the thermal conductive element 9.

In the first embodiment, the thermal conductive element 9 comprises a thermal conductive plate 91 which is arranged between the coil cores 25 and the thermal separating element 8a, 8b with respect to the axial direction A. The thermal conductive plate 91 is in very good thermal contact, preferably in physical contact, on the one hand with the thermal separating element 8a, 8b and on the other hand with the coil cores 25 or with the back iron 22. Preferably, the thermal conductive plate 91 is in physical contact with the first lower ends of all the coil cores 25, according to the representation, and with the back iron 22. Particularly preferably, the thermal conductive plate 91 rests against the back iron 22 over the entire circumference in order to be able to absorb heat from it as well as possible. To further improve the thermal contact between the coil cores 25 or the back iron 22 and the thermal conductive plate 91, it is possible to provide a thermally conductive paste, for example a thermal paste, between the thermal conductive plate 91 and the coil cores 25 or the back iron 22, which couples the adjoining components to each other particularly well in a thermal manner.

The thermal conductive element 9 further comprises a plurality of—here six-conductive teeth 92, each of which is connected to the thermal conductive plate 91. Each conductive tooth 92 extends from the thermal conductive plate 91 in the axial direction A in each case and is arranged radially inwardly with respect to the windings 61 in the interior space surrounded by the windings 61, as can be seen in particular in FIG. 2. Preferably, the number of conductive teeth 92 is equal to the number of coil cores 25 and exactly one conductive tooth 92 is arranged in front of each coil core 25. With respect to the radial direction, the conductive teeth 92 are arranged as close as possible to the longitudinal legs 26 of the coil cores 25 or the windings 61 arranged thereon, so that the conductive teeth 92 can absorb and dissipate the heat generated by the windings 61 and the coil cores 25 particularly well.

Furthermore, it is preferred that the thermal conductive element 9 is designed in one piece to minimize thermal resistance in the thermal conductive element 9. The thermal conductive element is made of a material with good thermal conductivity, for example a metallic material. A preferred material for the thermal conductive element 9 is aluminum.

It is a further preferred measure that, viewed in the circumferential direction, a notch 93 is provided in each case between two adjacent conductive teeth 9, which extends into the region of the first ends of the longitudinal legs 26 or up to the thermal conductive plate 91 with respect to the axial direction. Eddy currents or eddy current losses are minimized by these notches 93. Such eddy currents could be induced in the thermal conductive element 9 by the stray fields of the current flowing in the windings 61. The notches 93 lead to a significant reduction in eddy current losses in the thermal conductive element 9.

The arrangement of the conductive teeth 92 and the notches 93 located between them with respect to the circumferential direction is such that each conductive tooth 92 lies exactly opposite a longitudinal leg 26, and each notch 93 is arranged between two adjacent coil cores 25.

In the following, with reference to FIG. 4, the first variant of the first embodiment is explained in more detail, i.e. that variant in which the thermal separating element 8a is designed as an active cooling element. FIG. 4 shows this first variant of the first embodiment in a schematic sectional view in a section in axial direction A.

As can be clearly recognized in FIG. 4, the motor housing 20 and the control housing 41 of the control unit 40, which is different from the motor housing 20, are not in direct physical contact with each other, but are separated from each other by the thermal separating element 8a, which is arranged between the motor housing 20 and the control housing 41 with respect to the axial direction A. On one side, the thermal separating element 8a rests against the motor housing 20, i.e. it is in physical contact with the motor housing 20. On the other side, the thermal separating element 8a rests against the control housing 41, i.e. it is in physical contact with the control housing 41.

For better understanding, FIG. 5 shows a sectional view of the thermal separating element 8a of the first variant in a section perpendicular to the axial direction A. The thermal separating element 8a is designed in the form of a plate and substantially has the shape of a circular disk. At least one passage 85 is provided in the thermal separating element 8a, which extends completely through the thermal separating element 8a in the axial direction. As shown in FIG. 4—several such passages 85 are preferably provided. The passages 85 serve that signal connections from the control unit 40 can be passed through the thermal separating element 8a into the motor unit 30, for example electrical lines for supplying the windings 61 with electrical energy.

The separating element 8a is preferably made of a metallic material, for example of a steel or of a stainless steel. Furthermore, the outer surfaces of the thermal separating element 8a, i.e. those surfaces that are in contact with the environment, can be provided with a coating (not shown).

As FIG. 4 in particular shows, both the thermal conductive plate 91 of the thermal conductive element 9 and also the motor housing 20 rest against the thermal separating element 8a in order to ensure the best possible thermal connection of the thermal separating element 8a to the back iron 22, the windings 61, the coil cores 25 and the motor housing 20. In doing so. it is possible that the heat generated in the stator 2 during operation, which is primarily due to iron losses and copper losses, is efficiently and reliably dissipated into the thermal separating element 8a.

On the side facing away from the motor unit 30, the thermal separating element 8a rests against the control housing 41 of the control unit 40 in order to ensure a very good thermal contact between the control unit 40 and the thermal separating element 8a. The control housing 41 has several openings 43 (see FIG. 1), through which signal connections (not represented) can be passed from the control unit 40 through the passages 85 of the thermal separating element 8a into the motor unit 30, for example electrical lines for supplying the windings 61 with electrical energy.

The control housing 41 further comprises a control housing cover 412, which closes, preferably hermetically seals, the control housing 41 at its axial end face facing away from the thermal separating element 8a. The control housing cover 412 is preferably made of a metallic material, for example aluminum. The control housing cover 412 is designed with one or more feedthrough(s) (not represented), through which a supply cable for feeding in electrical energy or an interface cable for controlling the electromagnetic rotary drive 1 and/or for data exchange can be passed from the outside into the control housing 41.

The control unit 40 comprises at least one, preferably several, circuit boards 44, 45 on which the electronic components 42 of the control unit 40 are arranged. Each circuit board 44, 45 is preferably designed as an electronic print or PCB (printed circuit board). In the embodiment described here, the control unit 40 comprises a controller circuit board 44 and a supply circuit board 45, which are arranged parallel to each other and offset from each other with respect to the axial direction A.

The supply circuit board 45 comprises all those electronic components 42 that provide a direct current voltage with which, in particular, the windings 61 can be supplied with electrical energy. Since the electromagnetic rotary drive 1 is typically connected to an external alternating current source (not represented), for example to a technical three-phase alternating current source with three phases or to a common single-phase alternating current source with an alternating current voltage of 200-240 volts, a rectifier or inverter is provided on the supply circuit board 45, which converts the alternating current voltage into a direct current voltage, which is then used, for example, as an intermediate circuit voltage for controlling the windings 61. The inverter comprises circuit breakers 420 for rectification and the PFC circuit. Furthermore, filter components 421 are provided on the supply circuit board 45, e.g. capacitors or inductors for smoothing the direct current.

Those electronic components which are required for controlling the windings 61 to realize the drive and levitation function are provided on the controller circuit board 44. In particular, these are the circuit breakers 422 for controlling the windings 61. The intermediate circuit voltage required for the circuit breakers 422 is provided by the supply circuit board 45. Furthermore, regulation and control components for controlling the contactless magnetic levitation and the contactless magnetic drive are provided on the controller circuit board 44 as well, as an option, evaluation components for sensor signals (not represented).

In order to keep the switching losses as low as possible, the circuit breakers 420, 422 are preferably made of silicon carbide.

In order to ensure the best possible thermal connection between the circuit boards 44, 45 and the control housing 41, the circuit boards—as shown in FIG. 4—are arranged directly at the control housing 41 so that the circuit boards 44, 45 are in physical contact with the control housing 41. The circuit breakers 420, 422 as main heat sources are arranged in the regions of the circuit boards 44, 45 which rest against the control housing 41. Optionally, the regions of the circuit boards 44, 45 resting against the control housing 41 can be designed with a copper surface and/or with a thermal pad in order to achieve even better thermal coupling.

Both with respect to the motor unit 30 and also with respect to the control unit 40, the thermal connections between the individual components and the thermal connection to the thermal separating element 8a can be further improved, depending on the design, by providing a thermally conductive paste, for example a thermal paste, between components that are adjacent to each other.

In the design of the thermal separating element 8a as an active cooling element, at least one cooling conduit 81 (FIG. 5) is arranged in the thermal separating element 8a, through which a cooling fluid can flow, which dissipates heat from the thermal separating element 8a. The cooling conduit 81 extends as a continuous conduit from a first cooling connection 811 through the interior of the thermal separating element 8a to a second cooling connection 812, through which the cooling fluid can be introduced into the cooling conduit 81 or can be discharged from the cooling conduit 81. The cooling connections 811, 812 are each provided at the outer circumferential surface of the thermal separating element 8a, so that the cooling fluid can be fed into the cooling conduit 81 from outside the separating element 8a by means of, for example, the first cooling connection 811 and can be discharged again from the separating element 8a by means of the second cooling connection 812.

The cooling conduit 81 is designed in such a way that it passes through as many regions of the thermal separating element 8a as possible in order to dissipate a large amount of heat as efficiently as possible. In the embodiment of the cooling conduit 81 represented in FIG. 5 with an exemplary nature, it comprises several straight bores 813, which are arranged and designed in such a way that they complement each other to form the continuous cooling conduit 81, which connects the two cooling connections 811, 812 with each other. Each of the bores 813 is drilled from the outer circumferential surface of the thermal separating element 8a into the interior of the thermal separating element 8a. Subsequently, all bores 813 except the two that begin at the cooling connections 811, 812 are each closed at their end located in the outer circumferential surface, for example in each case with a screw 814 and a seal 815, so that the cooling fluid can only be introduced into the cooling conduit 81 or discharged from the cooling conduit 81 through the two cooling connections 811 and 812.

The cooling fluid is preferably a liquid, for example water. A particularly preferred cooling fluid is demineralized or deionized water (DI water). DI water is a typical cooling fluid, which is often used, for example, in the production facilities of the semiconductor industry.

The thermal separating element 8a is preferably made of a stainless steel or a rustproof steel. Such a steel also has the advantage that it is more corrosion resistant than copper, for example. In particular, when DI water is used as a cooling fluid, which is more aggressive than, for example, normal water, it is advantageous to make the thermal separating element 8a from a rustproof steel or from a stainless steel.

The externally exposed surfaces of the thermal separating element 8a can be coated, for example with an epoxy resin (epoxy), polytetrafluoroethylene (PTFE), ethylene tetrafluoroethylene (ETFE) or another plastic, in particular for such applications which require an increased chemical resistance.

The same applies to the externally exposed surfaces of all components of the electromagnetic rotary drive 1 which consist of a metallic material, i.e., for example the motor housing 20 and the control housing 41. These can be coated in the same way to increase their chemical resistance.

In the following with reference to FIG. 6, the second variant of the first embodiment is explained in more detail, i.e. that variant in which the thermal separating element 8b is designed as a passive thermal separating element 8b, i.e. as such a thermal separating element 8b that does not have a cooling fluid flowing through it. The heat generated during operation is mainly dissipated to the environment via convection. FIG. 6 shows this second variant of the first embodiment in a schematic sectional view in a section in axial direction A.

In the following description of the second variant, only the differences from the first variant will be looked at. The same parts or parts equivalent in function of the second variant are designated with the same reference signs as in the first variant. In particular, the reference signs have the same meaning as already explained in connection with the first variant. It is understood that all previous explanations of the first variant also apply in the same way or in the analogously same way to the second variant.

In the second variant, the thermal separating element 8b is substantially designed in a ring-shaped manner (see also FIG. 1) and forms a thermal insulating between the motor unit 30 and the control unit 40. With respect to the axial direction A, the thermal separating element 8b is arranged between the motor housing 20 and the control housing 41 in such a way that it prevents a direct contact between the motor housing 20 and the control housing 41. On one side, the motor housing 20 rests against the thermal separating element 8b and on the other side the control housing 41 rests against the thermal separating element 8b.

Preferably, the outer diameter of the thermal separating element 8b is at most as large as the outer diameter of the motor housing 20 or the outer diameter of the control housing 41, wherein it is also preferred that the outer diameter of the motor housing 20 is at least substantially the same size as the outer diameter of the control housing 41.

The schematic representation in FIG. 6 shows an embodiment in which the outer diameters of the motor housing 20, the thermal separating element 8b and the control housing 41 are all substantially the same size. However, such embodiments are also possible in which the outer diameter of the thermal separating element 8b is smaller than the outer diameter of the control housing 41 or the motor housing 20. Such an embodiment is illustrated in FIG. 1. In that end face of the control housing 41 which faces the thermal separating element 8b, a substantially circular-shaped housing recess 411 is provided which receives the thermal separating element 8b. In the analogously same way, a substantially same housing recess is arranged in that end face of the motor housing 20 facing the thermal separating element 8b, but this cannot be seen in FIG. 1. The depths of the housing recess 411 and the housing recess in the motor housing 20, by which is meant their respective extension in the axial direction A, are dimensioned such that the motor housing 20 and the control housing 41 do not touch each other in the assembled state but are separated from each other by an air gap. This means that the sum of the depth of the housing recess 411 in the control housing 41 and the depth of the housing recess in the motor housing 20 is smaller than the thickness of the ring-shaped thermal separating element 8b, by which is meant its extension in axial direction A. As a result, in the assembled state, there is a ring-shaped air gap between the motor housing 20 and the control housing 41, which contributes to the thermal insulation between the motor housing 20 and the control housing 41.

It is understood that this embodiment with the housing recess 411 in the control housing 41 and with the housing recess in the motor housing 20 can also be realized in the analogously same way in the first variant.

The thermal separating element 8b of the second variant, which is designed as a passive separating element for thermally decoupling the motor unit 30 from the control unit 40, is preferably made of a plastic. In particular for applications in chemically aggressive environments, a chemically resistant plastic such as polypropylene is preferred.

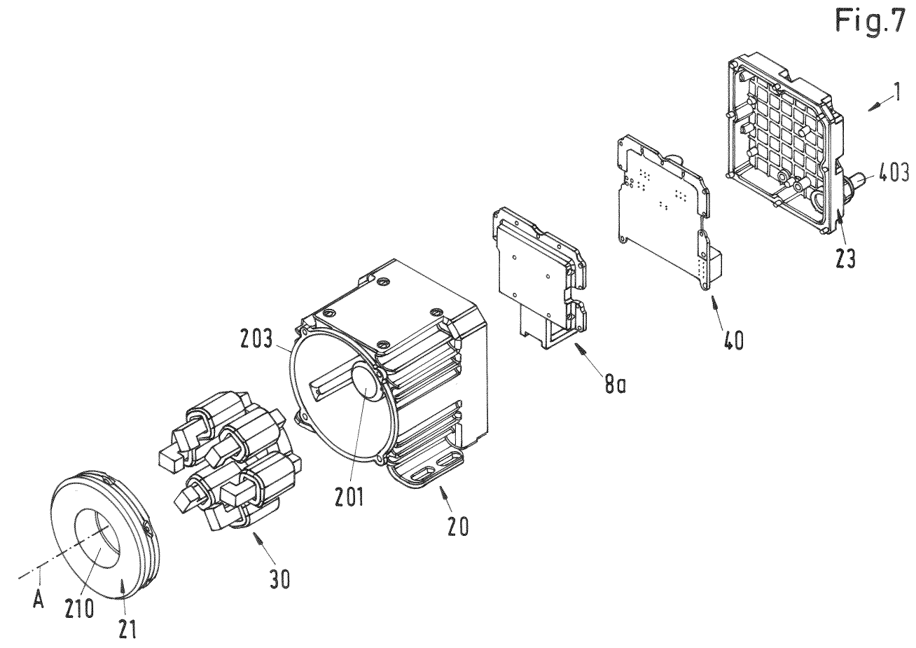

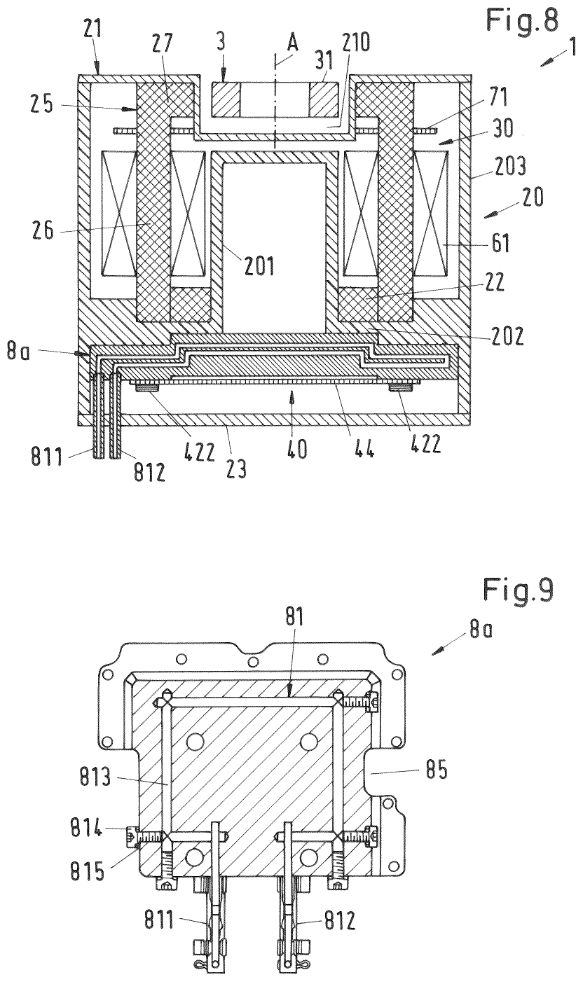

FIG. 7 shows a perspective exploded view of a second embodiment of an electromagnetic rotary drive 1 according to the disclosure. For better understanding. FIG. 8 still shows a schematic sectional view of the second embodiment in a section along the axial direction A.

In the following, only the differences from the first embodiment will be looked at. The same parts or parts equivalent in function of the second embodiment are designated with the same reference signs as in the first embodiment. In particular, the reference signs have the same meaning as already explained in connection with the first embodiment. It is understood that all previous explanations of the first embodiment and its two variants also apply in the same way or in the analogously same way to the second embodiment.

In the second embodiment, the control unit 40 is arranged in the motor housing 20, i.e. no separate control housing 41 is provided, but the control unit 40 is located in the motor housing 20.

This somewhat structurally simpler design of the second embodiment of the electromagnetic rotary drive 1, in which only one common housing is provided, namely the motor housing 20, is particularly suitable for smaller rotary drives 1, meaning rotary drives 1 that have a less high output, for example a maximum of 1000 watts or a maximum of 600 watts. With such outputs, it is possible to dispense with two separate, thermally separated housings, namely one for the motor unit and one for the control unit.

Also in this embodiment, in which the control unit 40 is arranged in the motor housing 20, the thermal separating element 8a, 8b can be designed as an active cooling element 8a, which has at least one inner cooling conduit 81 through which a cooling fluid, for example water, in particular DI water, can flow, or as a passive separating element 8b between the motor unit 30 and the control unit 40, i.e. without inner cooling conduits.

FIG. 7 and FIG. 8 show an embodiment in which the thermal separating element 8a is designed as an active cooling element. For better understanding, FIG. 9 shows, in a representation analogous to FIG. 5., this thermal separating element 8a in a sectional view in a section perpendicular to the axial direction A.

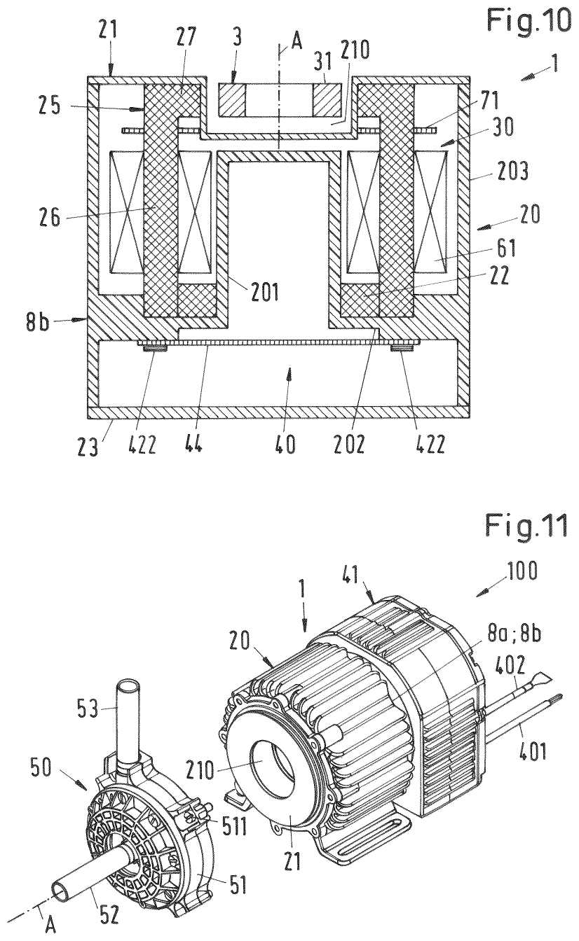

FIG. 10 shows a schematic sectional view of a variant of the second embodiment, in which the thermal separating element 8b is designed as a passive thermal separating element between the motor unit 30 and the control unit 40.

With reference to FIGS. 7 to 9, the design of the second embodiment is now described, in which the thermal separating element 8a is designed as an active cooling element.

As already mentioned, no separate control housing is provided in the second embodiment, but both the motor unit 30 and the control unit 40 are arranged in the motor housing 20. The motor housing 20 is delimited at its one axial end by the rotor cup 21, into the recess 210 of which the rotor 3 with the magnetically effective core 31 can be inserted.

The motor housing 20 is closed at the other axial end by a housing cover 23. The housing cover 23 is preferably made of a plastic. In particular for applications in chemically aggressive environments, a chemically resistant plastic such as polypropylene is preferred.

Also in the second embodiment, the motor housing 20 is preferably designed in a hermetically sealed manner. For this purpose, the motor housing 20 is connected in a hermetically sealed manner to the rotor cup 21 and the housing cover 23, for example screwed. In this case, seals, in particular flat seals, can be provided between the motor housing 20 and the rotor cup 21 or the housing cover 23.

According to a preferred measure, the motor housing 20 (see in particular FIG. 8) comprises an inner cup 201 which is substantially designed in a cylindrical manner, and which is arranged radially inwards with respect to the windings 61 in the interior space surrounded by the windings 61. The inner cup 201 is connected to the outer wall 203 of the motor housing 20 via a flange-like projection 202. The outer wall 203 forms the radially outward delimitation of the motor housing 20. Particularly preferably, the inner cup 201 and the flange-like projection 202 are an integral part of the motor housing 20. The outer wall 203, the flange-like projection 202 and the inner cup 201 are designed in their entirety in one piece and form the preferably one-piece motor housing 20.

In contrast to the first embodiment, the thermal conductive element 9 is not provided in the second embodiment. Instead, in the second embodiment, the inner cup 201 and the flange-like projection 202 are provided in order to absorb the heat generated by the windings 61, the coil cores 25 and the back iron 22. This heat is then dissipated with the aid of the thermal separating element 8a, which is designed as an active cooling element, wherein a part of this heat is also dissipated by means of convection, in particular via the outer wall 203 of the motor housing 20.

The flange-like projection 202, which connects the outer wall 203 of the motor housing 20 to the inner cup 201, is arranged between the coil cores 25 and the thermal separating element 8a with respect to the axial direction A. The flange-like projection 202 is in very good thermal contact, preferably in physical contact, on the one hand with the thermal separating element 8a and on the other hand with the coil cores 25 or with the back iron 22. Preferably, the flange-like projection 202 is in physical contact with the first lower ends of all coil cores 25, according to the representation (FIG. 8), and with the back iron 22. Particularly preferably, the flange-like projection 202 rests against the back iron 22 over the entire circumference in order to be able to absorb heat from the latter as well as possible. In order to further improve the thermal contact between the coil cores 25 or the back iron 22 and the flange-like projection 202, it is possible to provide a thermally conductive paste, for example a thermal paste, between the flange-like projection 202 and the coil cores 25 or the back iron 22, which thermally couples the adjoining components to each other particularly well.

The inner cup 201 connected to the flange-like projection 202 extends from the radially inner edge of the flange-like projection 202 in axial direction A and is arranged radially inwardly with respect to the windings 61 in the interior space surrounded by the windings 61, as can be recognized in particular in FIG. 8. With respect to the radial direction, the inner cup 201 is arranged as close as possible to the longitudinal legs 26 of the coil cores 25 or the windings 61 arranged thereon, so that the inner cup 201 can absorb and dissipate the heat generated by the windings 61 and the coil cores 25 particularly well. With respect to the axial direction A, the inner cup 201 extends approximately to the upper end of the windings 61 according to the representation (FIG. 8). Thus, the inner cup 201 extends over the entire length of the windings 61 with respect to the axial direction A.

To assemble the motor unit 30, the one-piece motor housing 20, which comprises the inner cup 201, the flange-like projection 202 and the outer wall 203, is provided. The stator 2 with the windings 61 arranged on the coil cores 25 and the circuit board 71 is inserted into the motor housing 20. Subsequently, the motor housing 20 can be filled with the thermal casting compound and finally closed with the rotor cup 21 in a sealing manner.

The thermal separating element 8a is dimensioned such that it can be inserted into the motor housing 20. The thermal separating element 8a rests against the flange-like projection 202 of the motor housing 20 over as large an area as possible, i.e. it is in physical contact with the motor housing 20. In doing so, the best possible thermal contact between the flange-like projection 202 and the thermal separating element 8a is realized, so that a very good heat transfer from the flange-like projection 202 or the inner cup 201 to the thermal separating element 8a is made possible.

For better understanding, FIG. 9 shows a sectional view of the thermal separating element 8a of the second embodiment in a section perpendicular to the axial direction A. The thermal separating element 8a is designed in the form of a plate and substantially has a rectangular or square shape. At least one passage 85 is provided in the thermal separating element 8a in order to pass signal connections from the control unit 40 through the thermal separating element 8a into the motor unit 30, for example electrical lines for supplying the windings 61 with electrical energy.

As FIG. 9 in particular shows, the thermal separating element 8a rests against the flange-like projection 202 of the motor housing 20 in order to ensure the best possible thermal connection of the thermal separating element 8a to the back iron 22, the windings 61, the coil cores 25 and the motor housing 20. In this way, it is possible that the heat generated in the stator 2 during operation, which is mainly due to iron losses and copper losses, is efficiently and reliably dissipated into the thermal separating element 8a.

The controller circuit board 44 of the control unit 40 is arranged on the side of the thermal separating element 8a facing away from the motor unit 30, which controller circuit board 44 is arranged directly on the thermal separating element 8a in order to ensure a very good thermal contact between the control unit 40 and the thermal separating element 8a. In this way, the heat generated in the control unit 40 can be efficiently dissipated into the thermal separating element 8a.

As represented in FIG. 9, the thermal separating element 8a, which is designed as an active cooling element, comprises the at least one cooling conduit 81 through which the cooling fluid can flow, which removes heat from the thermal separating element 8a. The cooling conduit 81 extends as a continuous conduit from the first cooling connection 811 through the interior of the thermal separating element 8a to the second cooling connection 812, through which the cooling fluid can be introduced into the cooling conduit 81 or can be discharged from the cooling conduit 81. The cooling connections 811, 812 each extend in axial direction A through the housing cover 23 (see FIG. 8), so that the cooling fluid can be fed into the cooling conduit 81 from outside the motor housing 20 by means of the first cooling connection 811, for example, and can be discharged again from the motor housing 20 by means of the second cooling connection 812.

The cooling conduit 81 is designed in such a way that it can dissipate a large amount of heat as efficiently as possible. In the embodiment of the cooling conduit 81 represented in FIG. 9 with an exemplary nature, the cooling conduit 81 comprises several straight bores 813, which are arranged and designed in such a way that they complement each other to form the continuous cooling conduit 81, which connects the two cooling connections 811, 812 with each other. Each of the bores 813 is drilled from the outside of the thermal separating element 8a into the interior of the thermal separating element 8a. Subsequently, all bores 813 except the two that begin at the cooling connections 811, 812 are each closed at their end located in the outside of the thermal separating element 8a, for example in each case with a screw 814 and a seal 815, so that the cooling fluid can only be introduced into the cooling conduit 81 or discharged from the cooling conduit 81 through the two cooling connections 811 and 812.

In the embodiment represented in FIG. 8, the controller circuit board 44 is again provided in the control unit 40. Those electronic components required for controlling the windings 61 to realize the drive and levitation function are provided on the controller circuit board 44. In particular, these are the circuit breakers 422 for controlling the windings 61. Furthermore, regulation and control components for controlling the contactless magnetic levitation and the contactless magnetic drive are provided on the controller circuit board 44 as well, as an option, evaluation components for sensor signals.

It is possible to dispense with a rectifier integrated into the control unit 40, in particular if the rotary drive 1 is designed for less high outputs of at most 600 watts, for example. Accordingly, no supply circuit board 45 is provided in the embodiment according to FIG. 8. A direct current voltage of 24 volts or 48 volts, for example, is then provided as the supply voltage from an external source (not represented). For this purpose, a feedthrough 403 (FIG. 8) is provided in the housing cover 23, through which the electrical energy in the form of the direct current voltage can be fed into the control unit 40 from a supply cable. The direct current voltage serves to provide the intermediate circuit voltage required for the circuit breakers 422 on the controller circuit board 44.

It is preferred to realize the circuit breakers 422 with MOSFETs, in particular for lower outputs.

In order to ensure the best possible thermal connection between the controller circuit board 44 and the thermal separating element 8a, the controller circuit board 44 is arranged directly at the thermal separating element 8a, so that the controller circuit board 44 is in physical contact with the thermal separating element 8a. The circuit breakers 422 as main heat sources in the control unit 40 are thus arranged as close as possible to the thermal separating element 8a. Optionally, the regions of the controller circuit board 44 resting against the thermal separating element 8a can be designed with a copper surface and/or with a thermal pad in order to achieve even better thermal coupling.

It is understood that such embodiments of the second embodiment of the electromagnetic rotary drive 1 according to the disclosure are also possible, in which the control unit 40 can comprise an internal rectifier for providing the supply voltage in the analogously same way as described for the first embodiment. This can then be arranged on a supply circuit board 45 in a manner analogous to that represented in FIG. 4 or in FIG. 6 and described with reference to these FIG. 4, FIG. 6.

With reference to FIG. 10, the variant of the second embodiment is now explained, in which the thermal separating element 8b is designed as a passive thermal separating element 8b between the motor unit 30 and the control unit 40, i.e. as such a thermal separating element 8b that does not have a cooling fluid flowing through it, but instead dissipates the absorbed heat to the environment mainly via convection.

In the variant of the second embodiment represented in FIG. 10, the thermal separating element 8b comprises the inner cup 201 and the flange-like projection 202, which are preferably an integral part of the motor housing 20. Preferably, the inner cup 201, the flange-like projection 202 and the outer wall 203 are designed in their entirety in one piece, which enables a particularly simple and cost-effective manufacture of the motor housing 20.

In this embodiment represented in FIG. 10, the thermal separating element 8b is thus an integral part of the motor housing 20. The thermal separating element 8b absorbs both the heat generated in the motor unit 30 and the heat generated in the control unit 40, which is then primarily dissipated to the environment by means of convection via the outer wall 203 of the motor housing 20.

The controller circuit board 44 is arranged directly on the flange-like projection 202, so that the controller circuit board 44 rests against the thermal separating element 8b. The circuit breakers 422 as main heat sources in the control unit 40 are preferably arranged in the regions of the controller circuit board 44 which rests against the thermal separating element 8b.

Furthermore, a centrifugal pump 100 for conveying a fluid is proposed by the disclosure, which is characterized in that the centrifugal pump 100 comprises an electromagnetic rotary drive 1 which is designed according to the disclosure, as well as a rotor 3 which can be driven for rotation with the electromagnetic rotary drive 1. The rotor 3 comprises a magnetically effective core 31, which is arranged in the recess 210 in the motor housing 20. The rotor 3 is designed as rotor 3 of the centrifugal pump 100.

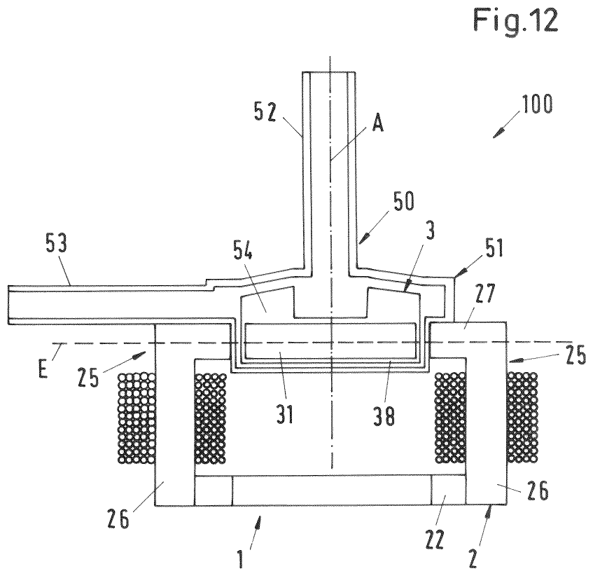

In a perspective view, FIG. 11 shows an embodiment of a centrifugal pump according to the disclosure, which is designated in its entirety by the reference sign 100. For better understanding, FIG. 12 shows a schematic sectional view of the embodiment from FIG. 11 in a section in the axial direction A. In FIG. 12, the motor housing 20, the control unit 40 and the thermal separating element 8a, 8b are not represented for better understanding.

The centrifugal pump 100 comprises a pump unit 50 with a pump housing 51, which comprises an inlet 52 and an outlet 53 for the fluid to be conveyed, wherein the rotor 3 is arranged in the pump housing 51 and comprises a plurality of vanes 54 for conveying the fluid. The pump unit 50 is designed in such a way that the pump unit 50 can be inserted into the recess 210 such that the magnetically effective core 31 of the rotor 3 is surrounded by the end faces 211 of the transverse legs 27.

In FIG. 11, the pump unit 50 is represented separately from the stator 2. In the embodiment of the centrifugal pump 100 described here, the electromagnetic rotary drive 1 is designed according to the first embodiment, i.e. it has the motor housing 20 and the control housing 41 separate from it, wherein the thermal separating element 8a or 8b is arranged between the motor housing 20 and the control housing 41, which can be designed as an active cooling element 8a or as a passive thermal separating element 8b.

It is understood that such embodiments of the centrifugal pump 100 are also possible, in which the electromagnetic rotary drive 1 is designed according to the second embodiment, in which no separate control housing 41 is provided, but the control unit 40 is arranged in the motor housing 20.

In the schematic representation of FIG. 12, the pump unit 50 is inserted into the recess 210 (not represented in FIG. 12) and thus into the stator 2. Furthermore, in FIG. 12, the radial plane in which the magnetically effective core 31 of the rotor 3 is magnetically levitated without contact is indicated by the dashed line with the reference sign E.

It is an advantageous aspect that the rotor 3 is designed as an integral rotor, because it is both the rotor 3 for the electromagnetic rotary drive 1 and the rotor 3 of the centrifugal pump 100 with which the fluid is conveyed. Altogether, the rotor 3 thus fulfills three functions in one: it is the rotor 3 of the electromagnetic rotary drive 1, it is the rotor 3 of the magnetic levitation, and it is the impeller with which the fluid or fluids are acted upon. This design as an integral rotor offers the advantage of a very compact and space-saving design.

The stator 2 is arranged in the motor housing 20, which is preferably designed as a hermetically sealed motor housing 20 and which encapsulates the stator 2. The circuit board 71 is also arranged in the motor housing 20. The stator housing 20 is preferably filled with a casting compound, for example with an epoxy resin or with a polyurethane, so that the stator 2 and possibly further components which are arranged inside the motor housing 20 are surrounded by the casting compound.

Furthermore, the motor housing 20 has the recess 210 in the rotor cup 21 at its end facing the pump unit 50, so that the pump unit 50 can be inserted into this recess 210. The rotor 3 provided in the pump housing 51 is then enclosed by this recess 210 in the motor housing 20, wherein the magnetically effective core 31 of the rotor 3 is arranged between the transverse legs 27 of the coil cores 25.

The pump housing 51 is fixed to the stator housing 20, preferably by means of a plurality of screws 511.

The control unit 40 comprises the control housing 41 in which the various electronic or electrical components 42 of the control unit 40, i.e. in particular also the controller circuit board 44 and the supply circuit board 45, are arranged. The control housing 41 is preferably designed as a hermetically sealed control housing 41, which encapsulates the electronic components 42. The control housing 41 is preferably filled with a casting compound, for example with an epoxy resin or with a polyurethane, so that the circuit boards 44, 45 and possibly further components which are arranged inside the control housing 41 are surrounded by the casting compound.

A supply cable 401 for feeding electrical energy into the control unit 40 and an interface cable 402 for controlling the electromagnetic rotary drive 1 and/or for data exchange is also represented in FIG. 11. For example, signals for controlling a programmable logic controller (PLC) to the control unit 40 are transmitted by means of the interface cable 402. The supply cable 401 and the interface cable 402 are connected to the interior of the control housing 41 via feedthroughs which are not shown in detail.

The rotor 3 comprises the plurality of vanes 54 for conveying the fluid. In the embodiment described here, for example, a total of four vanes 54 is provided, whereby this number has an exemplary character. The rotor 3 further comprises a jacket 38 with which the magnetically effective core 31 of the rotor 3 is enclosed and preferably hermetically encapsulated so that the magnetically effective core 31 of the rotor 3 does not come into contact with the fluid to be conveyed. All vanes 54 are arranged on the jacket 38 and arranged equidistantly with respect to the circumferential direction of the rotor 3. Each vane 54 extends outward in the radial direction and is connected to the jacket 38 in a torque-proof manner. The vanes 54 can be separate components that are then fixed to the jacket 38. Of course, it is also possible that all of the vanes 54 are an integral part of the jacket 38, i.e., that the jacket 38 is designed with all of the vanes 54 in one piece. The rotor 3 with the vanes 54 forms the wheel or the impeller of the centrifugal pump 100, with which the fluid or fluids are acted upon.

Depending on the application, it is preferred if the pump housing 51 of the pump unit 50 as well as the jacket 38 and the vanes 54 are made of one or more plastics. Suitable plastics are: polyethylene (PE), low density polyethylene (LDPE), ultra low density polyethylene (ULDPE), ethylene vinyl acetate (EVA), polyethylene terephthalate (PET), polyvinyl chloride (PVC), polypropylene (PP), polyurethane (PU), polyvinylidene fluoride (PVDF), acrylonitrile butadiene styrene (ABS), polyacrylic, polycarbonates (PC), polyetheretherketone (PEEK) or silicones. For many applications, the materials known under the brand name Teflon, polytetrafluoroethylene (PTFE) and perfluoroalkoxy polymers (PFA), are also suitable as plastic.

It is understood that the electromagnetic rotary drive according to the disclosure is also suitable for devices other than centrifugal pumps, for example for mixing devices for mixing flowable substances, for stirring devices, for example for mixing a fluid in a tank, for fans or also for devices for carrying and rotating wafers, for example in semiconductor manufacturing.

What is claimed is:

1. An electromagnetic rotary drive which is as a temple motor, comprising:
a motor unit;
a control unit, the motor unit arranged in a motor housing which has a recess to receive a ring-shaped or disk-shaped magnetically effective core of a rotor, the motor unit comprising a bearing and drive stator, with which the rotor is capable of being magnetically driven without contact in an operating state about a desired axis of rotation, which defines an axial direction, and with which the rotor is capable of being magnetically levitated without contact with respect to the stator, the rotor being actively magnetically levitated in a radial plane perpendicular to the axial direction, the stator having a plurality of coil cores, each coil core of the plurality of coil cores comprising a longitudinal leg so as to define a plurality of longitudinal legs, each longitudinal leg of the plurality of longitudinal legs extending from a first end in the axial direction to a second end, and having a transverse leg arranged at the second end in the radial plane, and extending in a radial direction, the plurality of coil cores arranged around the recess with respect to a circumferential direction, and a concentrated winding surrounding a respective longitudinal leg of the plurality of longitudinal leg, and the control unit equipped with electrical energy to control and supply the plurality of concentrated windings
a thermal separating element arranged with respect to the axial direction between the motor unit and the control unit so as to rest against the motor unit and the control unit, and configured to reduce a direct heat flow from the motor unit into the control unit.

2. The electromagnetic rotary drive according to claim 1, wherein a cooling conduit is arranged in the thermal separating element, through which a cooling fluid can is capable of flowing.

3. The electromagnetic rotary drive according to claim 1, wherein, with respect to the axial direction, a circuit board with electronic components is arranged between the at plurality of concentrated windings and the transverse leg of each of the plurality of longitudinal legs.

4. The electromagnetic rotary drive according to claim 1, wherein the control unit comprises a separate control housing arranged adjacent to the motor housing with respect to the axial direction, and the thermal separating element is arranged between the motor housing and the control housing with respect to the axial direction.

5. The electromagnetic rotary drive according to claim 4, wherein the motor housing and the control housing are arranged without direct physical contact with each other.

6. The electromagnetic rotary drive according to claim 1, wherein the stator comprises a thermal conductive element with a thermal conductive plate arranged between the plurality of coil cores and the thermal separating element with respect to the axial direction, and is in physical contact with the plurality of coil cores or with a back iron by which the first end of each longitudinal leg of the plurality of longitudinal legs is connected to conduct the magnetic flux.

7. The electromagnetic rotary drive according to claim 6, wherein the thermal conductive element comprises a plurality of conductive teeth connected to the thermal conductive plate, and each conductive tooth of the plurality of conductive teeth extends in the axial direction and is arranged radially inwardly with respect to the plurality of concentrated windings in an interior space surrounded by the plurality of concentrated windings.

8. The electromagnetic rotary drive according to claim 7, wherein each conductive tooth of the plurality of conductive teeth is arranged immediately adjacent to a respective longitudinal leg of the plurality of longitudinal legs or a respective concentrated winding of the plurality of concentrated windings with respect to the radial direction.

9. The electromagnetic rotary drive according to claim 7, wherein a number of the plurality of conductive teeth is equal to a number of the plurality of coil cores.

10. The electromagnetic rotary drive according to claim 7, wherein a notch is provided between two adjacent conductive teeth of the plurality of conductive teeth as viewed in the circumferential direction, the notch extending into an area of the first ends of the plurality of longitudinal legs with respect to the axial direction.

11. The electromagnetic rotary drive according to claim 1, wherein the control unit is arranged in the motor housing.

12. The electromagnetic rotary drive according to claim 11, wherein the thermal separating element is an integral part of the motor housing.

13. The electromagnetic rotary drive according to claim 11, wherein the motor housing comprises an inner cup which is substantially cylindrical, and is arranged radially inwardly with respect to the plurality of concentrated windings in an interior space surrounded by the plurality of concentrated windings.

14. The electromagnetic rotary drive according to claim 13, wherein the inner cup extends over an entire length of the plurality of concentrated windings with respect to the axial direction.

15. A centrifugal pump for conveying a fluid, the centrifugal pump comprises:
an electromagnetic rotary drive designed according to claim 1; and
a rotor with a magnetically effective core, which is arranged in the recess in the motor housing.
